(19) United States
(12) Patent Application Publication
(10) Pub. No.: US 2019/0019974 A1
(43) Pub. Date: Jan. 17, 2019

(54) METHOD OF MANUFACTURING DISPLAY DEVICE

(71) Applicant: Samsung Display Co., Ltd., Yongin-si (KR)

(72) Inventors: Wonmin YUN, Suwon-si (KR); Jongwoo KIM, Gwangmyeong-si (KR); Seungjae LEE, Seoul (KR); Youngcheol JOO, Hwaseong-si (KR); Jaeheung HA, Suwon-si (KR); Byoungduk LEE, Seongnam-si (KR); Yoonhyeung CHO, Yongin-si (KR)

(21) Appl. No.: 15/862,381

(22) Filed: Jan. 4, 2018

(30) Foreign Application Priority Data
Jul. 12, 2017 (KR) 10-2017-0088676

(51) Int. Cl. H01L 51/50; H01L 33/00; G02F 1/1333; H01L 27/15; H01L 27/32; H01L 21/02

(52) U.S. Cl. CPC H01L 51/5096; H01L 33/005; G02F 1/133305; H01L 2227/326; H01L 27/3209; H01L 21/0262; H01L 27/15

(57) ABSTRACT

A method of manufacturing a display device includes preparing an organic light-emitting device and forming an encapsulation member to encapsulate the organic light-emitting device. The forming of the encapsulation member includes forming a first inorganic encapsulation layer on the organic light-emitting device by providing a raw material gas on the organic light-emitting device, forming a first organic encapsulation layer by applying an organic material on the first inorganic encapsulation layer, and forming a second inorganic encapsulation layer on the first organic encapsulation layer. The raw material gas includes a nitrous oxide gas, a nitrogen gas, an ammonia gas, and a hydrogen gas, and a ratio of a sum of flow rates of the nitrous oxide gas and the nitrogen gas to a sum of flow rates of the ammonia gas and the hydrogen gas is about 1.1 or less.

### CROSS-REFERENCE TO RELATED APPLICATION

This application claims priority to and the benefit of Korean Patent Application No. 10-2017-0088676, filed on Jul. 12, 2017 in the Korean Intellectual Property Office, the entire content of which is herein incorporated by reference.

### BACKGROUND

### 1. Field

Aspects of embodiments of the present invention relate to a method of manufacturing a display device.

### 2. Description of the Related Art

An organic light-emitting display device includes an organic light-emitting device including an anode, an organic light-emitting layer, and a cathode. The organic light-emitting layer is susceptible to moisture (e.g., water) and oxygen. For example, when moisture or oxygen permeates into the organic light-emitting display device from the outside, the organic light-emitting layer may deteriorate, causing various defects, such as a dark spot, pixel shrinkage, and the like. Thus, an encapsulation part (e.g., an encapsulation layer) may be used to protect the organic light-emitting device.

### SUMMARY

Embodiments of the present invention are directed toward a method of manufacturing a display device during which a reduced amount of ultraviolet light occurs.

Embodiments of the present invention also provide a method of manufacturing a display device that improves light-emitting efficiency and life span of an organic light-emitting device.

According to an embodiment of the present invention, a method of manufacturing a display device includes preparing an organic light-emitting device and forming an encapsulation member to encapsulate the organic light-emitting device. The forming of the encapsulation member includes forming a first inorganic encapsulation layer on the organic light-emitting device by providing a raw material gas on the organic light-emitting device, forming a first organic encapsulation layer by applying an organic material on the first inorganic encapsulation layer, and forming a second inorganic encapsulation layer on the first organic encapsulation layer. The raw material gas includes a nitrous oxide (N₂O) gas, a nitrogen (N₂) gas, an ammonia (NH₃) gas, and a hydrogen (H₂) gas, and a ratio of a sum of flow rates of the nitrous oxide gas and the nitrogen gas to a sum of flow rates of the ammonia gas and the hydrogen gas is equal to or less than about 1.1.

The forming of the first inorganic encapsulation layer may include performing a plasma-enhanced chemical vapor deposition (PECVD) process or a plasma-enhanced atomic layer deposition (PEALD) process.

Ultraviolet light may occur during the forming of the first inorganic encapsulation layer, and an irradiation amount of the ultraviolet light may be equal to or less than about 1000 mJ/cm².

The ratio of the sum of the flow rates of the nitrous oxide gas and the nitrogen gas to the sum of the flow rates of the ammonia gas and the hydrogen gas may be equal to or greater than about 0.5.

The forming of the second inorganic encapsulation layer may include providing the raw material gas on the first organic encapsulation layer.

The first inorganic encapsulation layer may include at least one of silicon oxide (SiOₓ), silicon nitride (SiNₓ), or silicon oxynitride (SiOₓN_{y}).

The raw material gas may further include a silane (SiH₄) gas.

The forming of the first organic encapsulation layer may include performing a flash evaporation process, a screen printing process, or an inkjet process.

The method may further include forming a second organic encapsulation layer by applying an organic material on the second inorganic encapsulation layer after the forming of the second inorganic encapsulation layer, and forming a third inorganic encapsulation layer on the second organic encapsulation layer. The forming of the third inorganic encapsulation layer may include providing the raw material gas on the second organic encapsulation layer.

The second inorganic encapsulation layer and the third inorganic encapsulation layer may include at least one of silicon oxide (SiOₓ), silicon nitride (SiNₓ), or silicon oxynitride (SiOₓN_{y}).

The organic light-emitting device may include a first electrode, a second electrode facing the first electrode and adjacent to the encapsulation member, and a light-emitting layer between the first electrode and the second electrode and being for generating light. The light may be emitted in a direction from the first electrode toward the second electrode.

According to another embodiment of the present invention, a method of manufacturing a display device includes preparing an organic light-emitting device and forming an inorganic layer by depositing an inorganic material on the organic light-emitting device. The forming of the inorganic layer includes depositing a raw material gas on the organic light-emitting device by using plasma. The raw material gas includes a silane (SiH₄) gas a nitrous oxide (N₂O) gas, a nitrogen (N₂) gas, an ammonia (NH₃) gas, and a hydrogen (H₂) gas. A ratio of a sum of flow rates of the nitrous oxide gas and the nitrogen gas to a sum of flow rates of the ammonia gas and the hydrogen gas is equal to or less than about 1.1.

The method may further include forming an organic layer by applying an organic material on the inorganic layer, and forming an upper inorganic layer by depositing an inorganic material on the organic layer.

The forming of the upper inorganic layer may include depositing the raw material gas on the organic layer by using plasma.

Ultraviolet light may occur during the forming of the inorganic layer, and an irradiation amount of the ultraviolet light may be equal to or less than about 1000 mJ/cm².

The forming of the inorganic layer may include performing a plasma-enhanced chemical vapor deposition (PECVD) process or a plasma-enhanced atomic layer deposition (PEALD) process.

The inorganic layer may include at least one of silicon oxide (SiOₓ), silicon nitride (SiNₓ), or silicon oxynitride (SiOₓN_{y}).

The ratio of the sum of the flow rates of the nitrous oxide gas and the nitrogen gas to the sum of the flow rates of the ammonia gas and the hydrogen gas may be equal to or greater than about 0.5.

### BRIEF DESCRIPTION OF THE DRAWINGS

The above and other aspects and features of the present invention will become more apparent by describing, in further detail, exemplary embodiments thereof with reference to the accompanying drawings, in which:

FIG. 1A is a perspective view of a display device according to an embodiment of the present invention.

FIG. 1B is an exploded perspective view of the display device shown in FIG. 1.

FIG. 2 is a circuit diagram of one pixel included in the display device according to an embodiment of the present invention.

FIG. 3 is a schematic cross-sectional view of a portion of the display device according to an embodiment of the present invention.

FIGS. 4A and 4B are schematic cross-sectional views of a portion of an encapsulation member of the display device shown in FIG. 3.

FIG. 5 is a flowchart illustrating a method of manufacturing a display device, according to an embodiment of the present invention.

FIGS. 6A-6D are cross-sectional views of some processes of a method of manufacturing a display device according to an embodiment of the present invention.

FIG. 7 is a graph illustrating device efficiency over time of an organic light-emitting device manufactured according to embodiments of the present invention.

FIGS. 8A-8D are graphs illustrating relationships between an irradiation amount of ultraviolet light and flow rates of gases including (or constituting) a raw material gas in a process of forming a lower inorganic layer of an encapsulation member according to an embodiment of the present invention.

### DETAILED DESCRIPTION

The present invention now will be described more fully hereinafter with reference to the accompanying drawings, in which various exemplary embodiments are shown. The present invention may, however, be embodied in many different forms and should not be construed as being limited to the exemplary embodiments set forth herein. Rather, these exemplary embodiments are provided so that this disclosure will be thorough and complete, and will fully convey the scope of the present invention to those skilled in the art.

It will be understood that when an element such as a layer, region, or substrate is referred to as being “on” another element, it can be directly on the other element or intervening elements may be present. The term “directly” means that there are no intervening elements. As used herein, the term “and/or” includes any and all combinations of one or more of the associated listed items. The terminology used herein is for the purpose of describing particular embodiments and is not intended to be limiting. As used herein, the singular forms “a” and “an” are intended to include the plural forms, including “at least one,” unless the content clearly indicates otherwise. “Or” means “and/or.” It will be further understood that the terms “comprises” and/or “comprising” or “includes” and/or “including” when used in this specification specify the presence of the stated features, regions, integers, steps, operations, elements, and/or components but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

Further, the use of “may” when describing embodiments of the present invention relates to “one or more embodiments of the present invention.” Expressions, such as “at least one of,” when preceding a list of elements, modify the entire list of elements and do not modify the individual elements of the list. Also, the term “exemplary” is intended to refer to an example or illustration. As used herein, the terms “use,” “using,” and “used” may be considered synonymous with the terms “utilize,” “utilizing,” and “utilized,” respectively.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings herein. Like reference numerals refer to like elements throughout. “About” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system).

Exemplary embodiments of the present invention are described herein with reference to cross-sectional illustrations and/or plane illustrations that are idealized exemplary illustrations. In the drawings, the thicknesses of layers and regions may be exaggerated for clarity. Accordingly, variations from the shapes in the illustrations as a result, for example, of manufacturing techniques and/or tolerances, are to be expected. Thus, exemplary embodiments should not be construed as limited to the shapes illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of exemplary embodiments.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A display device according to an embodiment of the present invention will be described hereinafter.

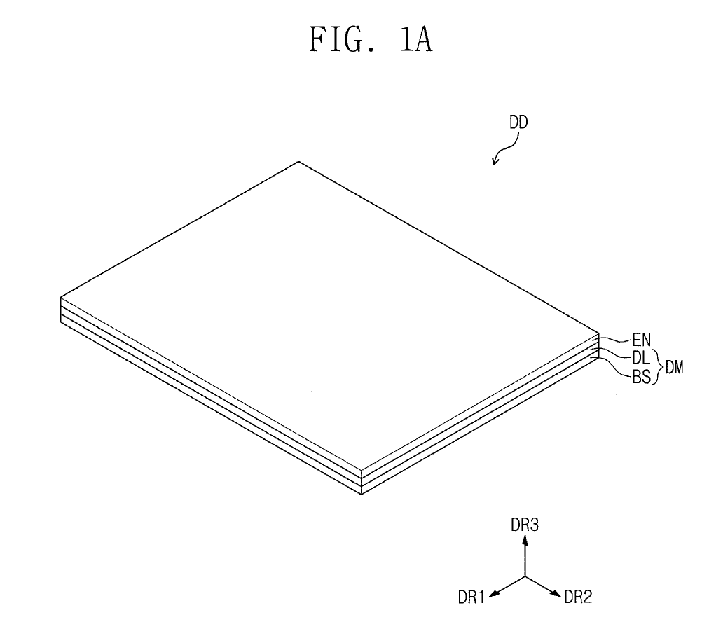

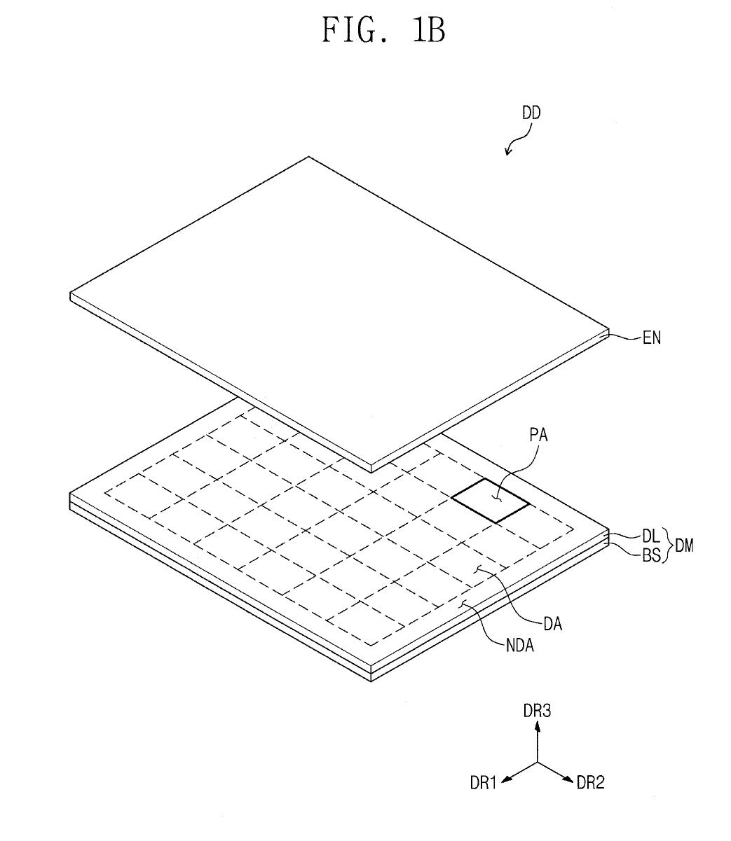

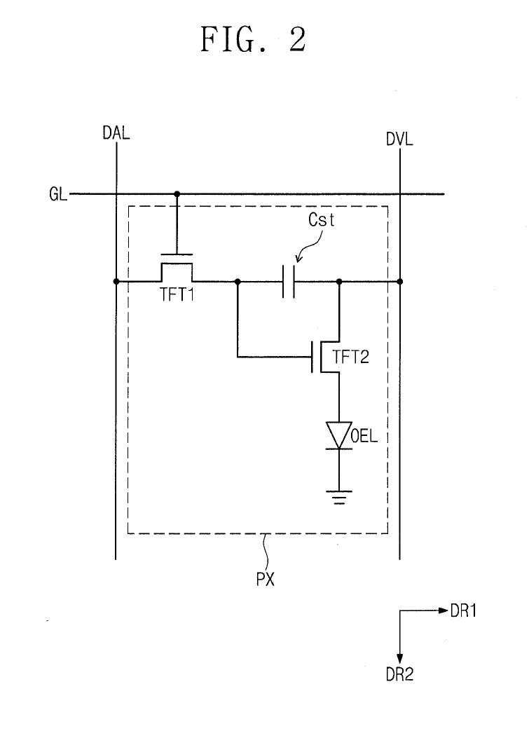

FIG. 1A is a perspective view of a display device according to an embodiment of the present invention, FIG. 1B is an exploded perspective view of the display device shown in FIG. 1, and FIG. 2 is a circuit diagram of one pixel included in the display device according to an embodiment of the present invention. Hereinafter, a display device DD according to an embodiment of the present invention will be described with reference to FIGS. 1A, 1B, and 2.

Referring to FIGS. 1A and 1B, the display device DD according to an embodiment of the present invention includes a display member DM and an encapsulation member EN.

The display member DM includes a display area DA and a non-display area NDA. The display area DA may display an image. The display area DA may have, but is not limited to, a substantially rectangular shape when viewed in a thickness direction D3 of the display device DD.

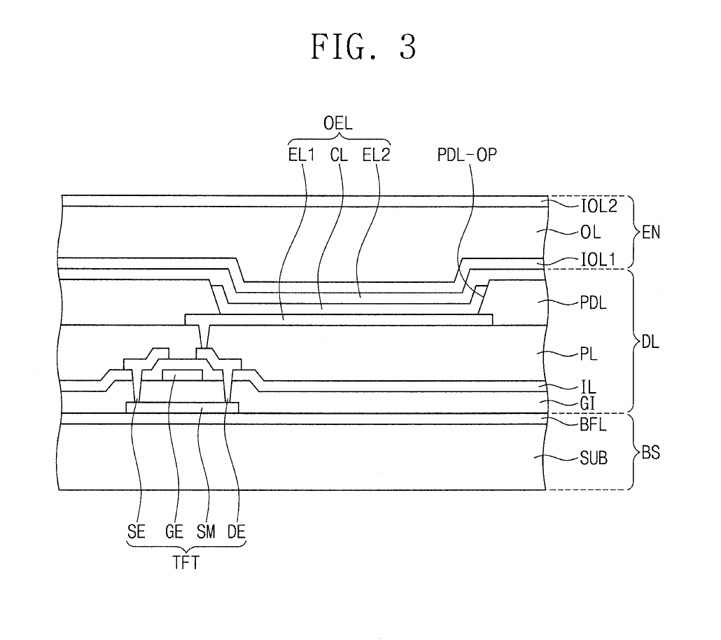

The display area DA includes a plurality of pixel areas PA. The pixel areas PA may be arranged in a matrix form. The pixel areas PA may be defined by a pixel defining layer PDL (see, e.g., FIG. 3). Each of the pixel areas PA may include a pixel PX (see, e.g., FIG. 2). Each of the pixels PX includes an organic light-emitting device OEL (see, e.g., FIG. 2).

The non-display area NDA may not display an image. For example, the non-display area NDA may surround the display area DA (e.g., may surround a periphery of the display area DA) when viewed in the thickness direction DR3 of the display device DD. The non-display area NDA may be adjacent to the display area DA in a first direction DR1 and a second direction DR2.

The display member DM may include a base member BS and a display layer DL disposed on the base member BS.

The base member BS may be a substrate including (or formed of) an insulating material, such as glass, plastic, or crystal. The display layer DL may include a plurality of the pixels PX. Each of the pixels PX may receive an electrical signal to generate light.

Referring to FIG. 2, each of the pixels PX may be connected to an interconnection part including a gate line GL, a data line DAL, and a driving voltage line DVL. Each of the pixels PX includes thin film transistors TFT1 and TFT2 connected to the interconnection part, the organic light-emitting device OEL, and a capacitor Cst. The organic light-emitting device OEL and the capacitor Cst are connected to the thin film transistors TFT1 and TFT2.

The gate line GL extends in the first direction DR1. The data line DAL extends in the second direction DR2 to cross the gate line GL. The driving voltage line DVL extends in substantially the same direction as the data line DAL (e.g., the second direction DR2). The gate line GL transmits a scan signal to the thin film transistors TFT1 and TFT2, the data line DAL transmits a data signal to the thin film transistors TFT1 and TFT2, and the driving voltage line DVL provides a driving voltage to the thin film transistors TFT1 and TFT2.

The thin film transistors TFT1 and TFT2 may include a driving thin film transistor TFT2 for controlling the organic light-emitting device OEL and a switching thin film transistor TFT1 for switching the driving thin film transistor TFT2. In the illustrated embodiment of the present invention, each of the pixels PX includes two thin film transistors TFT1 and TFT2. However, embodiments of the present invention are not limited thereto. In other embodiments, each of the pixels PX may include a single thin film transistor and a single capacitor or may include three or more thin film transistors and two or more capacitors.

The switching thin film transistor TFT1 includes a first gate electrode, a first source electrode, and a first drain electrode. The first gate electrode is connected to the gate line GL, and the first source electrode is connected to the data line DAL. The first drain electrode is connected to a first common electrode through a contact opening (e.g., a contact hole). The switching thin film transistor TFT1 transmits the data signal provided from the data line DAL to the driving thin film transistor TFT2 in response to the scan signal applied to the gate line GL.

The organic light-emitting device OEL includes a first electrode connected to the driving thin film transistor TFT2 and a second electrode for receiving a second power source voltage. The organic light-emitting device OEL may include a light-emitting pattern disposed between the first electrode and the second electrode.

The organic light-emitting device OEL emits light during a turn-on period (e.g., an emission period) of the driving thin film transistor TFT2. A color of the light generated by the organic light-emitting device OEL is determined by a material of the light-emitting pattern. For example, the color of the light generated from the organic light-emitting device OEL may be red, green, blue, or white.

Referring again to FIGS. 1A and 1B, the encapsulation member EN is disposed on the display member DM. The encapsulation member EN covers the display layer DL. The encapsulation member EN protects the display layer DL from external moisture (e.g., external water) and external contaminants. The encapsulation member EN will be described later in more detail.

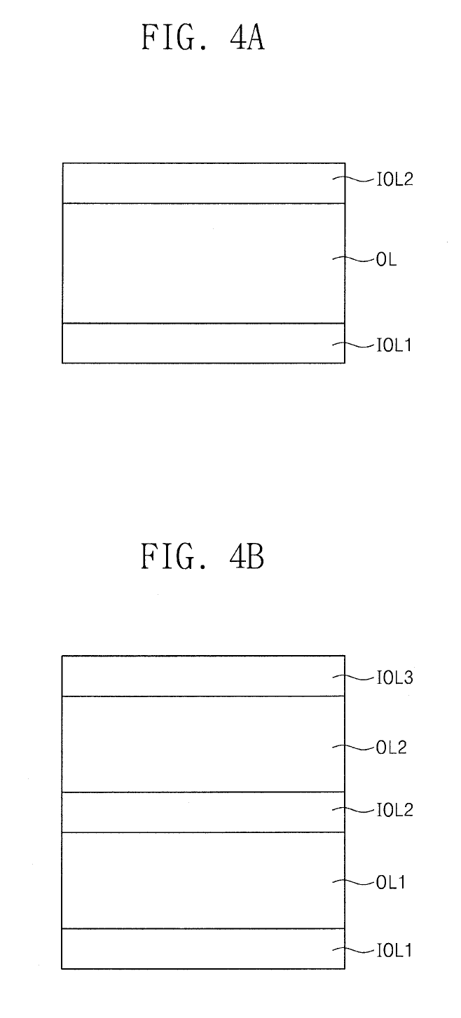

FIG. 3 is a schematic cross-sectional view of a portion of a display device according to an embodiment of the present invention. FIGS. 4A and 4B are schematic cross-sectional views of a portion of an encapsulation member of the display device shown in FIG. 3.

Referring to FIG. 3, a display device includes a base member BS, a display layer DL, and an encapsulation member EN.

The base member BS may include a base layer SUB and a buffer layer BFL. The base layer SUB may be formed of a generally used material. For example, the base layer SUB may include (or may be formed of) an insulating material, such as glass, plastic, or crystal. In an embodiment, an organic polymer of the base layer SUB may be polyethylene terephthalate (PET), polyethylene naphthalate (PEN), polyimide, and/or polyether sulfone (PES). The base layer SUB may be selected in consideration of mechanical strength, thermal stability, transparency, surface flatness, ease of handling, and/or waterproofing.

A functional layer may be disposed on the base layer SUB. In FIG. 3, the buffer layer BFL is the functional layer. However, in another embodiment, the functional layer may include a barrier layer. The buffer layer BFL may improve coupling strength between the base member BS and the display layer DL, and the barrier layer may prevent or substantially prevent foreign material from entering the display layer DL.

The display layer DL may include a thin film transistor TFT and an organic light-emitting device OEL.

The thin film transistor TFT may include a driving thin film transistor for controlling the organic light-emitting device OEL and a switching thin film transistor for switching the driving thin film transistor.

The thin film transistor TFT may include a semiconductor layer SM, a gate electrode GE, a source electrode SE, and a drain electrode DE. The semiconductor layer SM includes (or is formed of) a semiconductor material and acts as an active layer of the thin film transistor TFT. The semiconductor layer SM may include (or may be formed of) an inorganic semiconductor or an organic semiconductor.

A gate insulating layer GI is disposed on the semiconductor layer SM. The gate insulating layer GI covers the semiconductor layer SM. The gate insulating layer GI may include at least one of an organic insulating material or an inorganic insulating material.

The gate electrode GE is disposed on the gate insulating layer Gl. The gate electrode GE may be formed to cover an area corresponding to a channel region of the semiconductor layer SM.

An interlayer insulating layer IL is disposed on the gate electrode GE and the gate insulating layer GI. The source electrode SE and the drain electrode DE is disposed on the interlayer insulating layer IL. The drain electrode DE may contact a drain region of the semiconductor layer SM through a contact opening (e.g., a contact hole) formed in the gate insulating layer GI and the interlayer insulating layer IL, and the source electrode SE may contact a source region of the semiconductor layer SM through a contact opening (e.g., a contact hole) formed in the gate insulating layer GI and the interlayer insulating layer IL.

A passivation layer PL is disposed on the source electrode SE, the drain electrode DE, and the interlayer insulating layer IL. The passivation layer PL may act as a protective layer for protecting the thin film transistor TFT and/or may act as a planarization layer having a planarized top surface.

The organic light-emitting device OEL is disposed on the passivation layer PL.

The organic light-emitting device OEL includes a first electrode EL1, a second electrode EL2 disposed on the first electrode EL1, and an intermediate layer CL disposed between the first electrode EL1 and the second electrode EL2.

The first electrode EU may be a pixel electrode (e.g., an anode). The first electrode EL1 may be a transparent electrode, a semitransparent electrode, or a reflective electrode. The first electrode EL1 may include (or may be formed of) a conductive compound including a metal, a metal alloy, or a metal oxide. The first electrode EL1 may include a transparent metal oxide, for example, indium tin oxide (ITO), indium zinc oxide (IZO), zinc oxide (ZnO), or indium tin zinc oxide (ITZO). In some embodiments, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride/calcium (LiF/Ca), lithium fluoride/aluminum (LiF/Al), molybdenum (Mo), titanium (Ti), a compound thereof, or a mixture thereof (e.g., a mixture of Ag and Mg). In some embodiments, the first electrode EL1 may have a multi-layer structure including a reflective layer or semitransparent layer including (or formed of) the above exemplified material(s) and a transparent conductive layer including (or formed of) indium tin oxide (ITO), indium zinc oxide (IZO), zinc oxide (ZnO), or indium tin zinc oxide (ITZO).

The second electrode EL2 may be a common electrode (e.g., a cathode). The second electrode EL2 may be a transparent electrode, a semitransparent electrode, or a reflective electrode. The second electrode EL2 may include (or may be formed of) a conductive compound including a metal, a metal alloy, or a metal oxide. The second electrode EL2 may include a transparent metal oxide, for example, indium tin oxide (ITO), indium zinc oxide (IZO), zinc oxide (ZnO), or indium tin zinc oxide (ITZO). In some embodiments, the second electrode EL2 may include Ag, Mg, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In some embodiments, the second electrode EL2 may have a multi-layer structure that includes a reflective layer or semitransparent layer including (or formed of) one or more of the above exemplified materials and a transparent conductive layer including (or formed of) indium tin oxide (ITO), indium zinc oxide (IZO), zinc oxide (ZnO), and/or indium tin zinc oxide (ITZO).

The first electrode EL1 may be the reflective electrode, and the second electrode EL2 may be the semitransparent electrode or the transparent electrode. The display device DD according to an embodiment of the present invention may include a front surface type organic light-emitting device OEL (e.g., a top emission organic light-emitting device OEL). However, embodiments of the present invention are not limited thereto. In some embodiments, the organic light-emitting device OEL may be a back surface light-emitting type (e.g., a bottom emission organic light-emitting device OEL).

A pixel defining layer PDL may be disposed on the first electrode EL1. For example, the pixel defining layer PDL may cover a portion of the first electrode EL1 and may expose another portion of the first electrode EL1.

The pixel defining layer PDL may define an opening PDL-OP. The opening PDL-OP in the pixel defining layer PDL may define a light-emitting area.

The intermediate layer CL may be disposed between the first electrode EL1 and the second electrode EL2. The intermediate layer CL may include a light-emitting layer. The intermediate layer CL may further include a plurality of organic layers in addition to the light-emitting layer. For example, the intermediate layer CL may include a hole injection layer, a hole transfer layer, the light-emitting layer, an electron transfer layer, and an electron injection layer which are sequentially stacked. In addition to these layers, the intermediate layer CL may further include a hole stop layer, a hole buffer layer, and/or an electron stop layer.

The intermediate layer CL may be disposed in the opening PDL-OP defined in the pixel defining layer PDL. The intermediate layer CL may overlap the light-emitting area defined by the opening PDL-OP in the pixel defining layer PDL. In FIG. 3, the intermediate layer CL is patterned to be confined in the opening PDL-OP in the pixel defining layer PDL. However, embodiments of the present invention are not limited thereto. In some embodiments, at least one layer of the intermediate layer CL may be disposed as a common layer and may be disposed on an entire portion of (e.g., disposed on all of) the first electrode EL1 and an entire portion of (e.g., over the entire or substantially entire surface of) the pixel defining layer PDL.

The encapsulation member EN includes a first inorganic layer IOL1, an organic layer OL disposed on the first inorganic layer IOL1, and a second inorganic layer IOL2 disposed on the organic layer OL. The encapsulation member EN is disposed on the organic light-emitting device OEL and encapsulates the organic light-emitting device OEL.

The first inorganic layer IOL1 is disposed on the display member DM. The first inorganic layer IOL1 is disposed on the organic light-emitting device OEL. For example, the first inorganic layer IOL1 may contact a top surface of the second electrode EL2 of the organic light-emitting device OEL. The first inorganic layer IOL1 may overlap the organic light-emitting device OEL and the pixel defining layer PDL.

The first inorganic layer IOL1 includes an inorganic material. The first inorganic layer IOL1 may be an inorganic thin film including the inorganic material. For example, the inorganic material may include at least one of, but is not limited to, silicon oxide (SiOₓ), silicon nitride (SiNₓ), or silicon oxynitride (SiOₓN_{y}). The first inorganic layer IOL1 may encapsulate the organic light-emitting device OEL and may function as a barrier layer for preventing foreign material from entering the organic light-emitting device OEL. Hereinafter, the first inorganic layer IOL1 is referred to as a “first inorganic encapsulation layer IOL1” for ease and convenience of description.

The organic layer OL is disposed on the first inorganic encapsulation layer IOL1. The organic layer OL may contact a top surface of the first inorganic encapsulation layer IOL1. The organic layer OL includes an organic material. For example, the organic material may include at least one of, but is not limited to, polyacrylate, polyethylene terephthalate, polyethylene naphthalate, polycarbonate, polyimide, polyethylene sulfonate, polyoxymethylene, or polyarylate. In some embodiments, the organic material may include a silicon-based organic compound.

The organic layer OL may have a thickness and may act as a protective layer for protecting the organic light-emitting device OEL from external impacts. In addition, the organic layer OL may act as a planarization layer that is disposed on the first inorganic encapsulation layer IOL1 and has a planarized top surface. Hereinafter, the organic layer OL is referred to as an “organic encapsulation layer OL” for ease and convenience of description.

The second inorganic layer IOL2 is disposed on the organic encapsulation layer OL. The second inorganic layer IOL2 may be disposed directly on the organic encapsulation layer OL. The second inorganic layer IOL2 may overlap the organic light-emitting device OEL and the pixel defining layer PDL. The second inorganic layer IOL2 may completely overlap the first inorganic encapsulation layer IOL1 when viewed in a plan view (e.g., when viewed in a top-down view).

The second inorganic layer IOL2 includes an inorganic material. The second inorganic layer IOL2 may be an inorganic thin film including the inorganic material. The second inorganic layer IOL2 may include the same or a substantially similar inorganic material as the inorganic material included in the first inorganic encapsulation layer IOL1. For example, the second inorganic layer IOL2 may include at least one of silicon oxide (SiOₓ), silicon nitride (SiNₓ), or silicon oxynitride (SiOₓN_{y}). The second inorganic layer IOL2 may encapsulate the organic light-emitting device OEL and may function as a barrier layer for preventing foreign material from entering the organic light-emitting device OEL. The second inorganic layer IOL2 may also function as a barrier layer for preventing foreign material from entering the organic encapsulation layer OL.

Hereinafter, the second inorganic layer IOL2 is referred to as a “second inorganic encapsulation layer IOL2” for ease and convenience of description.

Referring to FIGS. 4A and 4B, the encapsulation member according to some embodiments of the present invention may include a plurality of inorganic encapsulation layers and at least one organic encapsulation layer. As illustrated in FIG. 4A, the encapsulation member according to an embodiment of the present invention may have a three-layer structure in which the first inorganic encapsulation layer IOL1, the organic encapsulation layer OL, and the second inorganic encapsulation layer IOL2 are sequentially stacked. In another embodiment, as illustrated in FIG. 4B, the encapsulation member may have a five-layer structure in which a first inorganic encapsulation layer IOL1, a first organic encapsulation layer OL1, a second inorganic encapsulation layer IOL2, a second organic encapsulation layer OL2, and a third inorganic encapsulation layer IOL3 are sequentially stacked. However, embodiments of the present invention are not limited thereto, and the layered structure of the encapsulation member may be variously modified.

A method of manufacturing a display device according to an embodiment of the present invention will be described hereinafter.

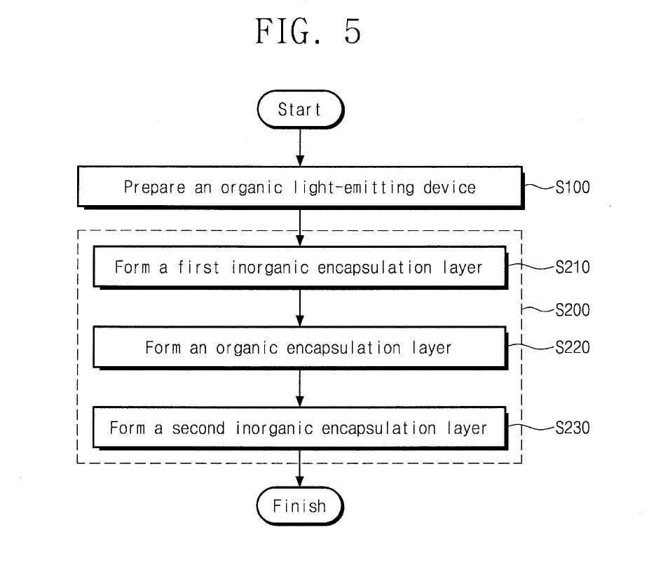

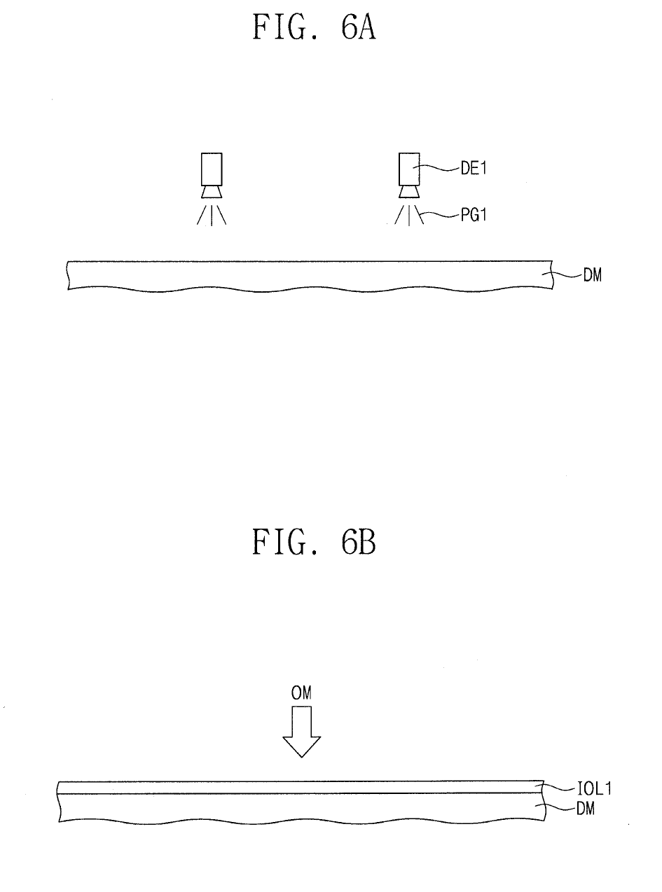

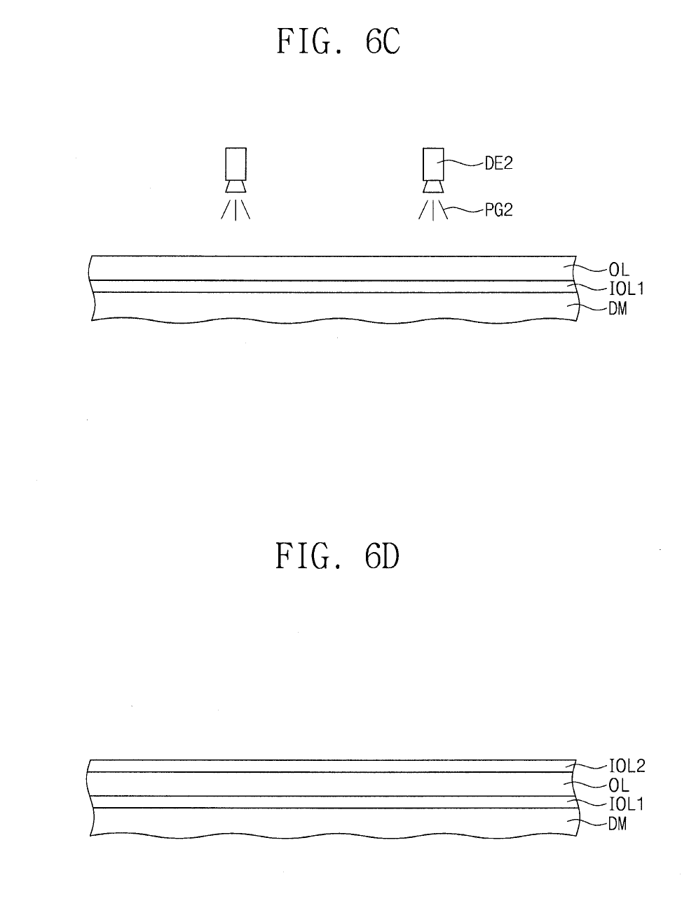

FIG. 5 is a flowchart illustrating a method of manufacturing a display device according to an embodiment of the present invention. FIGS. 6A-6D are cross-sectional views of some processes of a method of manufacturing a display device according to an embodiment of the present invention.

Referring to FIG. 5, a method of manufacturing a display device according to an embodiment of the present invention includes preparing a display member (S100) and forming an encapsulation member on the display member (S200). In some embodiments, the display member includes an organic light-emitting device, and the encapsulation member is formed to encapsulate the organic light-emitting device.

According to an embodiment of the present invention, the formation of the encapsulation member (S200) includes forming a first inorganic encapsulation layer IOL1 (S210), forming an organic encapsulation layer OL (S220), and forming a second inorganic encapsulation layer IOL2 (S230).

Referring to FIGS. 6A and 6B, the formation of the encapsulation member according to an embodiment of the present invention includes forming the first inorganic encapsulation layer IOL1 (S210) by depositing an inorganic material on the display member DM after preparing the display member DM (S100).

The formation of the first inorganic encapsulation layer IOL1 includes providing (e.g., depositing) a first raw material gas PG1 on (or onto) the display member DM. In some embodiments, the first raw material gas PG1 includes a silane (SiH₄) gas, a nitrous oxide (N₂O) gas, a nitrogen (N₂) gas, an ammonia (NH₃) gas, and a hydrogen (H₂) gas.

The first raw material gas PG1 is deposited in a plasma state on the display member DM. The formation of the first inorganic encapsulation layer IOL1 may include depositing the first raw material gas PG1 on the display member DM by using a plasma-enhanced chemical vapor deposition (PECVD) process or a plasma-enhanced atomic layer deposition (PEALD) process. The first raw material gas PG1 may include both a source gas and a reaction gas in the plasma deposition process.

A first deposition apparatus DE1 may provide the first raw material gas PG1 on (or onto) the display member DM and may deposit the first raw material gas PG1 on the display member DM as plasma. The first deposition apparatus DE1 may include a source gas supply, a reaction gas supply, a purge gas supply, a gas controller, and a plasma generator. The first deposition apparatus DE1 may include a process chamber.

A ratio of a sum of a flow rate of the nitrous oxide gas and a flow rate of the nitrogen gas to a sum of a flow rate of the ammonia gas and a flow rate of the hydrogen gas is equal to or less than about 1.1 in the first raw material gas PG1. For example, the sum of the flow rates of the nitrous oxide gas and the nitrogen gas may be equal to or less than about 1.1 times the sum of the flow rates of the ammonia gas and the hydrogen gas in the first raw material gas PG1. In some embodiments, the ratio of the sum of the flow rates of the nitrous oxide gas and the nitrogen gas to the sum of the flow rates of the ammonia gas and the hydrogen gas may be equal to or greater than about 0.5 and equal to or less than about 1.1 in the first raw material gas PG1.

Ultraviolet light may occur (e.g., may be produced) during the formation of the first inorganic encapsulation layer IOL1 (S210). The ultraviolet light may occur during the plasma deposition process used to form the first inorganic encapsulation layer IOL1. The ultraviolet light may occur (e.g., may be produced) by a plasma gas including nitrogen (N) atoms when the first inorganic encapsulation layer IOL1 is formed. An irradiation amount of the ultraviolet light during the formation of the first inorganic encapsulation layer IOL1 may be about 1000 mJ/cm² or less.

Referring to FIGS. 6B and 6C, the formation of the encapsulation member according to an embodiment of the present invention includes forming the organic encapsulation layer OL on the first inorganic encapsulation layer IOL1 (S220).

The organic encapsulation layer OL may be formed by applying an organic material OM to the first inorganic encapsulation layer IOL1. The organic material OM is an organic material for forming the organic encapsulation layer OL. The organic material OM may be a monomer for forming a polymer compound, such as polyacrylate, polyethylene terephthalate, polyethylene naphthalate, polycarbonate, polyimide, polyethylene sulfonate, polyoxymethylene, or polyarylate. The organic material OM may be, for example, an acrylic-based monomer. However, embodiments of the present invention are not limited thereto. In another embodiment, the organic material OM may include a silicon-based organic compound.

The formation of the organic encapsulation layer OL may include performing a flash evaporation process, a screen printing process, or an inkjet process. The formation of the organic encapsulation layer OL may further include hardening the applied organic material OM after applying the organic material OM to a top surface of the first inorganic encapsulation layer IOL1 by using the flash evaporation process, the screen printing process, or the inkjet process.

Referring to FIGS. 6C and 6D, the formation of the encapsulation member according to an embodiment of the present invention includes forming the second inorganic encapsulation layer IOL2 on the organic encapsulation layer OL (S230).

The second inorganic encapsulation layer IOL2 may be formed by depositing an inorganic material on the organic encapsulation layer OL.

For example, the second inorganic encapsulation layer IOL2 may be formed by providing (e.g., depositing) a second raw material gas PG2 on (or onto) the organic encapsulation layer OL. The second raw material gas PG2 may include a silane gas, a nitrous oxide gas, a nitrogen gas, an ammonia gas, and a hydrogen gas.

The second raw material gas PG2 may be deposited on the organic encapsulation layer OL by using plasma. The formation of the second inorganic encapsulation layer IOL2 may include depositing the second raw material gas PG2 on the organic encapsulation layer OL by using a plasma-enhanced chemical vapor deposition (PECVD) process or a plasma-enhanced atomic layer deposition (PEALD) process. The second raw material gas PG2 may include both a source gas and a reaction gas in the plasma deposition process. The second inorganic encapsulation layer IOL2 may be formed by the same or a substantially similar process as the first inorganic encapsulation layer IOL1.

A second deposition apparatus DE2 may provide the second raw material gas PG2 on (or onto) the organic encapsulation layer OL and may deposit the second raw material gas PG2 on the organic encapsulation layer OL by using plasma. The second deposition apparatus DE2 may include a source gas supply, a reaction gas supply, a purge gas supply, a gas controller, and a plasma generator. The second deposition apparatus DE2 may include a process chamber. The second deposition apparatus DE2 may be the same as or substantially similar to the first deposition apparatus DE1.

A ratio of a sum of a flow rate of the nitrous oxide gas and a flow rate of the nitrogen gas to a sum of a flow rate of the ammonia gas and a flow rate of the hydrogen gas may be equal to or less than about 1.1 in the second raw material gas PG2. For example, the sum of the flow rates of the nitrous oxide gas and the nitrogen gas may be equal to or less than about 1.1 times the sum of the flow rates of the ammonia gas and the hydrogen gas in the second raw material gas PG2. In some embodiments, the ratio of the sum of the flow rates of the nitrous oxide gas and the nitrogen gas to the sum of the flow rates of the ammonia gas and the hydrogen gas may be equal to or greater than about 0.5 and equal to or less than about 1.1 in the second raw material gas PG2. The second raw material gas PG2 may have the same or a substantially similar composition as the first raw material gas PG1.

Ultraviolet light may occur during the formation of the second inorganic encapsulation layer IOL2 (S230). The ultraviolet light may occur due to the plasma deposition process during the formation of the second inorganic encapsulation layer IOL2. The ultraviolet light may be generated by a plasma gas including nitrogen (N) atoms when the second inorganic encapsulation layer IOL2 is formed. An irradiation amount of the ultraviolet light occurring during the formation of the second inorganic encapsulation layer IOL2 may be about 1000 mJ/cm² or less.

The formation of the encapsulation member, according to an embodiment, may further include forming the second organic encapsulation layer OL2 (see, e.g., FIG. 4B) on the second inorganic encapsulation layer IOL2 after the formation of the second inorganic encapsulation layer IOL2 and forming the third inorganic encapsulation layer IOL3 (see, e.g., FIG. 4B) on the second organic encapsulation layer OL2.

The second organic encapsulation layer OL2 may be formed by the same or a substantially similar process as the organic encapsulation layer OL, described above. For example, the second organic encapsulation layer OL2 may be formed by applying an organic material to a top surface of the second inorganic encapsulation layer IOL2 by using a flash evaporation process, a screen printing process, or an inkjet process.

The third inorganic encapsulation layer IOL3 may be formed by the same or a substantially similar process as the first inorganic encapsulation layer IOL1, described above. For example, the third inorganic encapsulation layer IOL3 may be formed by providing (e.g., depositing) a raw material gas including a silane gas, a nitrous oxide gas, a nitrogen gas, an ammonia gas, and a hydrogen gas on (or onto) the second organic encapsulation layer OL2. The third inorganic encapsulation layer IOL3 may be formed by using a plasma-enhanced chemical vapor deposition (PECVD) process or a plasma-enhanced atomic layer deposition (PEALD) process. A ratio of a sum of flow rates of the nitrous oxide gas and the nitrogen gas to a sum of flow rates of the ammonia gas and the hydrogen gas may be equal to or less than about 1.1 in the raw material gas. In some embodiments, the ratio of the sum of the flow rates of the nitrous oxide gas and the nitrogen gas to the sum of the flow rates of the ammonia gas and the hydrogen gas may be equal to or greater than about 0.5 and equal to or less than about 1.1 in the raw material gas.

In the method of manufacturing the display device according to an embodiment of the present invention, the ultraviolet light may occur when the inorganic layer of the encapsulation member is formed. For example, the ultraviolet light may occur from the plasma gas when the inorganic layer is formed through the plasma-enhanced chemical vapor deposition (PECVD) process or the plasma-enhanced atomic layer deposition (PEALD) process. The gas from which the ultraviolet light occurs may be a nitrogen-based plasma gas. If an excess amount (or intensity) of ultraviolet light occurs during the formation of the inorganic layer of the encapsulation member, the ultraviolet light may damage an inner organic layer of the organic light-emitting device, thereby deteriorating a life span and a light-emitting efficiency of the organic light-emitting device. For example, if an excess amount of ultraviolet light occurs during the process of forming the inorganic layer that contacts an upper portion of the organic light-emitting device, the life span and the light-emitting efficiency of the organic light-emitting device may be greatly deteriorated. When the second electrode of the upper portion of the organic light-emitting device is a transparent electrode and the organic light-emitting device is a front-surface type organic light-emitting device, the ultraviolet light occurring during the process may permeate into the organic light-emitting device, thereby greatly deteriorating the life span and the light-emitting efficiency of the organic light-emitting device.

In the method of manufacturing the display device according to an embodiment of the present invention, the irradiation amount of the ultraviolet light occurring during the formation of the inorganic layer may be reduced by adjusting a composition of the raw material gas used to form the inorganic layer of the encapsulation member. For example, in the method of manufacturing the display device according to an embodiment of the present invention, the ratio of the sum of the flow rates of the nitrous oxide gas and the nitrogen gas to the sum of the flow rates of the ammonia gas and the hydrogen gas is adjusted to about 1.1 or less in the raw material gas for forming the inorganic layer, and thus, the irradiation amount of the ultraviolet light may be about 1000 mJ/cm² or less. Because the irradiation amount of the ultraviolet light is maintained at about 1000 mJ/cm² or less during the method of manufacturing the display device according to an embodiment of the present invention, it is possible to inhibit or prevent the light-emitting layer of the organic light-emitting device from being damaged by the ultraviolet light. As a result, deterioration of the life span and the light-emitting efficiency of the organic light-emitting device can be reduced, minimized, or prevented.

In addition, if the ratio of the sum of the flow rates of the nitrous oxide gas and the nitrogen gas to the sum of the flow rates of the ammonia gas and the hydrogen gas is less than about 0.5 in the raw material gas for forming the inorganic layer, the inorganic layer having the barrier characteristic for blocking moisture (e.g., water) and oxygen may not be suitably formed. However, in the method of manufacturing the display device according to an embodiment of the present invention, the ratio of the sum of the flow rates of the nitrous oxide gas and the nitrogen gas to the sum of the flow rates of the ammonia gas and the hydrogen gas may be equal to or greater than about 0.5 and equal to or less than about 1.1 in the raw material gas for forming the inorganic layer, and thus, the inorganic layer having the barrier characteristic for blocking moisture and oxygen may be formed and the irradiation amount of the ultraviolet light during the process can be reduced. As a result, it is possible to reduce or prevent deterioration of the life span and the light-emitting efficiency of the organic light-emitting device.

Hereinafter, embodiments of the present invention will be described in more detail with reference to experimental examples thereof. However, the following experimental examples are provided to describe aspects and features of embodiments of the present invention, and the scope of the present invention is not limited by the following experimental examples.

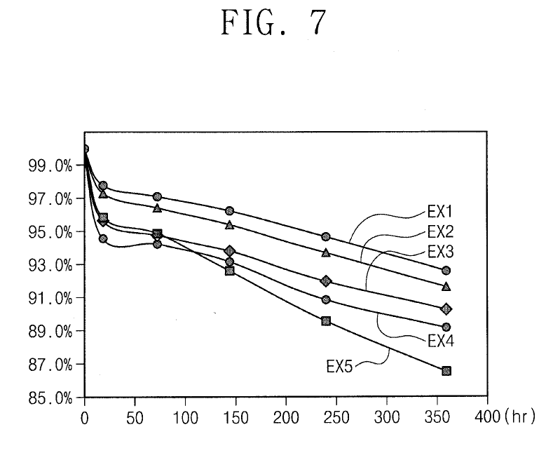

FIG. 7 is a graph illustrating device efficiency over time of organic light-emitting devices manufactured according to embodiments of the present invention.

In FIG. 7, each of manufactured examples included an organic light-emitting device having a three-layer encapsulation member including a lower inorganic layer, an organic layer, and an upper inorganic layer. Irradiation amounts of ultraviolet light occurring in processes of forming the lower inorganic layers in the manufactured examples were different from each other, and device efficiency over time of each of the manufactured examples was measured. In FIG. 7, the x-axis represents a device driving time, and the unit of the x-axis is hours (hr). In FIG. 7, the y-axis represents a value (%) of a light-emitting efficiency of a device. Here, the light-emitting efficiency of an initially driven device is set to 100%.

A first example EX1 is a time-device efficiency graph of a manufactured example in which the irradiation amount of the ultraviolet light occurring during the process of forming the lower inorganic layer is 282 mJ/cm². A second example EX2 is a time-device efficiency graph of a manufactured example in which the irradiation amount of the ultraviolet light occurring during the process of forming the lower inorganic layer is 764 mJ/cm². A third example EX3 is a time-device efficiency graph of a manufactured example in which the irradiation amount of the ultraviolet light occurring during the process of forming the lower inorganic layer is 834 mJ/cm². A fourth example EX4 is a time-device efficiency graph of a manufactured example in which the irradiation amount of the ultraviolet light occurring during the process of forming the lower inorganic layer is 948 mJ/cm². A fifth example EX5 is a time-device efficiency graph of a manufactured example in which the irradiation amount of the ultraviolet light occurring during the process of forming the lower inorganic layer is 1300 mJ/cm².

Referring to the graphs of the first-fifth examples EX1-EX5, the device efficiency over time decreases greater as the irradiation amount of the ultraviolet light occurring during the process of forming the lower inorganic layer increases. For example, when the irradiation amount of the ultraviolet light occurring during the process of forming the lower inorganic layer is about 1000 mJ/cm² or less, such as in the first-fourth examples EX1-EX4, the device efficiency over time does not substantially decease and the device efficiency is maintained at about 90% or more after about 350 hours. When the irradiation amount of the ultraviolet light occurring during the process of forming the lower inorganic layer is greater than about 1000 mJ/cm², such as in the fifth example EX5, the device efficiency over time substantially decreases and the device efficiency is reduced to about 87% or less after about 350 hours.

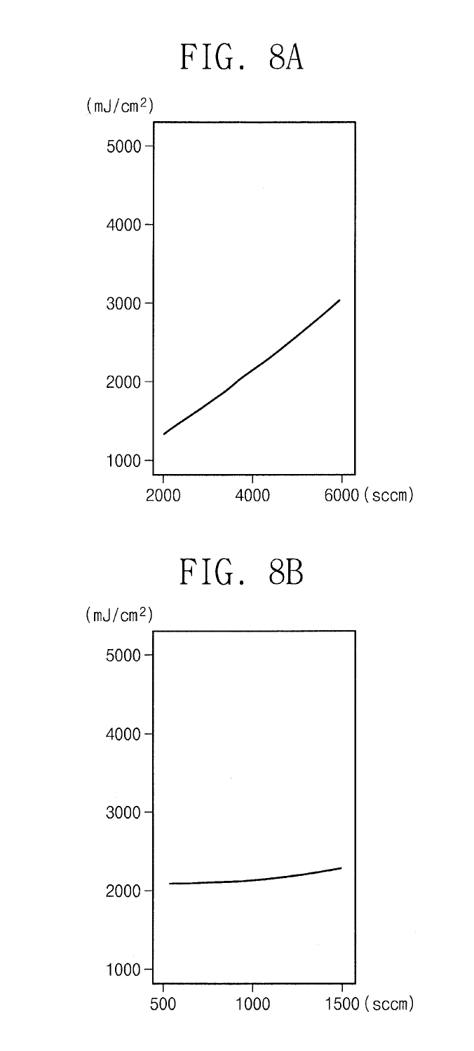

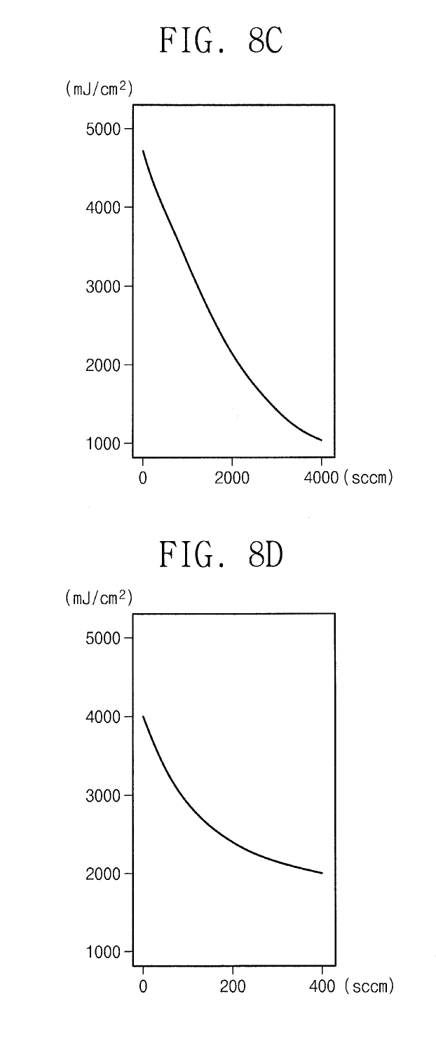

FIGS. 8A-8D are graphs illustrating relationships between an irradiation amount of ultraviolet light and flow rates of gases including (constituting) a raw material gas in a process of forming a lower inorganic layer included in an encapsulation member of an organic light-emitting device according to embodiments of the present invention. FIGS. 8A-8D show average values of irradiation amounts of ultraviolet light with respect to flow rates of gases including (constituting) a raw material gas through a design of experiment (DOE) method, respectively. In FIGS. 8A-8D, the x-axis represents a flow rate of each of the gases and the x-axis unit is standard cubic centimeters per minute (sccm). In FIGS. 8A-8D, the y-axis represents the average value of the irradiation amount of the ultraviolet light and the y-axis unit is mJ/cm².

FIG. 8A is a graph illustrating an average value change of the irradiation amount of the ultraviolet light with respect to the flow rate of the nitrogen (N₂) gas. FIG. 8B is a graph illustrating an average value change of the irradiation amount of the ultraviolet light with respect to the flow rate of the nitrous oxide (N₂O) gas. FIG. 8C is a graph illustrating an average value change of the irradiation amount of the ultraviolet light with respect to the flow rate of the hydrogen (H₂) gas. FIG. 8D is a graph illustrating an average value change of the irradiation amount of the ultraviolet light with respect to the flow rate of the ammonia (NH₃) gas.

Referring to FIGS. 8A-8D, during the process of forming the lower inorganic layer included in the encapsulation member of the organic light-emitting device according to embodiments of the present invention, the amount of the ultraviolet light occurring during the process increases as a concentration of the nitrogen gas in the raw material gas increases. A concentration of the nitrous oxide gas has a relatively small influence on the amount of the occurring ultraviolet light. However, the amount of the ultraviolet light occurring during the process slightly increases as the concentration of the nitrous oxide gas increases. The amount of the ultraviolet light occurring during the process decreases as a concentration of the hydrogen gas in the raw material gas increases. Likewise, the amount of the ultraviolet light occurring during the process decreases as a concentration of the ammonia gas in the raw material gas increases. Referring to these characteristics, in the method of manufacturing the display device according to an embodiment of the present invention, the concentration of the hydrogen gas and the ammonia gas may be maintained at a certain ratio or more with respect to the concentration of the nitrogen gas and the nitrous oxide gas in the raw material gas, such that the amount of the ultraviolet light occurring during the process of forming the inorganic layer may be reduced to a certain level or less. As a result, it is possible to prevent the life span and the light-emitting efficiency of the device from being deteriorated or substantially deteriorated due to the ultraviolet light occurring during the formation of the inorganic layer.

The following table 1 shows the irradiation amount of the ultraviolet light according to a gas composition ratio of the gases including (constituting) the raw material gas during the process of forming the lower inorganic layer included in the encapsulation member of the organic light-emitting device according to embodiments of the present invention. In the following table 1, a unit of the irradiation amount of the ultraviolet light is mJ/cm². In the following table 1, a numerical value of each gas indicates a ratio of the flow rate of each gas to the flow rate of the silane gas when the flow rate of the silane gas is 2. In the following table 1, the “gas composition ratio” indicates a ratio of a sum of the flow rates of the nitrogen gas and the nitrous oxide gas to a sum of the flow rates of the ammonia gas and the hydrogen gas. In other words, the gas composition ratio represents “(the flow rate of the nitrogen gas+the flow rate of the nitrous oxide gas)/(the flow rate of the ammonia gas+the flow rate of the hydrogen gas)”.

TABLE 1

| | | | | | Gas | Irradiation |
|---|---|---|---|---|---|---|
| | Ammo- | Nitrous | | | com- | amount of |
| Silane | nia | oxide | Nitrogen | Hydrogen | position | ultraviolet |
| (SiH₄) | (NH₃) | (N₂O) | (N₂) | (H₂) | ratio | light |
| 2 | 1 | 6 | 30 | 0 | 36 | 6232 |
| 2 | 1 | 9 | 20 | 0 | 29 | 4224 |
| 2 | 1 | 3 | 20 | 0 | 23 | 5341 |
| 2 | 1 | 6 | 10 | 0 | 16 | 3245 |
| 2 | 1 | 9 | 30 | 10 | 3.55 | 3651 |
| 2 | 1 | 3 | 30 | 10 | 3 | 2271 |
| 2 | 1 | 6 | 20 | 10 | 2.36 | 2142 |
| 2 | 2 | 9 | 10 | 10 | 1.73 | 1514 |
| 2 | 1 | 6 | 30 | 20 | 1.71 | 1581 |
| 2 | 1 | 9 | 20 | 20 | 1.38 | 1310 |
| 2 | 1 | 3 | 10 | 10 | 1.19 | 1522 |
| 2 | 1 | 3 | 20 | 20 | 1.1 | 833.8 |
| 2 | 1 | 6 | 10 | 20 | 0.76 | 678 |

Referring to the table 1, during the process of forming the lower inorganic layer of the encapsulation member for the organic light-emitting device according to embodiments of the present invention, the irradiation amount of the ultraviolet light substantially decreases as the ratio of the sum of the flow rates of the nitrogen gas and the nitrous oxide gas to the sum of the flow rates of the ammonia gas and the hydrogen gas decreases. For example, the irradiation amounts of the ultraviolet light are less than about 1000 mJ/cm² when the ratios of the sum of the flow rates of the nitrogen gas and the nitrous oxide gas to the sum of the flow rates of the ammonia gas and the hydrogen gas are about 1.1 or less, but the irradiation amounts of the ultraviolet light are greater than about 1000 mJ/cm² when the ratio is greater than about 1.1.

According to embodiments of the present invention, the ratio of the sum of the flow rates of the nitrogen gas and the nitrous oxide gas to the sum of the flow rates of the ammonia gas and the hydrogen gas is adjusted to be about 1.1 or less to maintain the irradiation amount of the ultraviolet light occurring during the process at about 1000 mJ/cm² or less during the process of forming the lower inorganic layer of the encapsulation member for the organic light-emitting device. Thus, the organic light-emitting device disposed under the lower inorganic layer may not be damaged (e.g., may not be substantially damaged) by the ultraviolet light. For example, a conductive polymer layer (e.g., the light-emitting layer included in the organic light-emitting device disposed under the lower inorganic layer) may not be damaged (e.g., may not be substantially damaged) by the ultraviolet light. Thus, the light-emitting efficiency and the life span of the organic light-emitting device may not be deteriorated or substantially deteriorated.

In addition, if the ratio of the sum of the flow rates of the nitrogen gas and the nitrous oxide gas to the sum of the flow rates of the ammonia gas and the hydrogen gas is less than about 0.5, the inorganic layer may not have the barrier function (e.g., may not have a sufficient barrier characteristic). However, during the process of forming the lower inorganic layer of the encapsulation member for the organic light-emitting device according to an embodiment of the present invention, the ratio of the sum of the flow rates of the nitrogen gas and the nitrous oxide gas to the sum of the flow rates of the ammonia gas and the hydrogen gas is adjusted to be equal to or greater than about 0.5 and equal to or less than about 1.1. Thus, the lower inorganic layer has the barrier characteristic for blocking moisture and oxygen, and the irradiation amount of the ultraviolet light occurring during the process can be reduced. As a result, the life span and the light-emitting efficiency of the organic light-emitting device may not be deteriorated or substantially deteriorated.

According to a method of manufacturing the display device in an embodiment of the present invention, the amount of the ultraviolet light occurring during the manufacturing process may be reduced to reduce the irradiation amount of the ultraviolet light entering the organic light-emitting device, and thus, the display device, which includes the organic light-emitting device, may have an improved life span and light-emitting efficiency.

While the present invention has been described with reference to example embodiments, it will be apparent to those skilled in the art that various changes and modifications may be made therein without departing from the spirit and scope of the present invention. Therefore, it should be understood that the above embodiments are not limiting but are illustrative. Thus, the scope of the present invention is to be determined by the broadest permissible interpretation of the following claims and their equivalents and shall not be restricted or limited by the foregoing description.

What is claimed is:

1. A method of manufacturing a display device, the method comprising:
preparing an organic light-emitting device; and
forming an encapsulation member to encapsulate the organic light-emitting device, the forming of the encapsulation member comprising:
forming a first inorganic encapsulation layer on the organic light-emitting device by providing a raw material gas on the organic light-emitting device;
forming a first organic encapsulation layer by applying an organic material on the first inorganic encapsulation layer; and
forming a second inorganic encapsulation layer on the first organic encapsulation layer,
wherein the raw material gas comprising a nitrous oxide (N₂O) gas, a nitrogen (N₂) gas, an ammonia (NH₃) gas, and a hydrogen (H₂) gas, and
wherein a ratio of a sum of flow rates of the nitrous oxide gas and the nitrogen gas to a sum of flow rates of the ammonia gas and the hydrogen gas is equal to or less than about 1.1.

2. The method of claim 1, wherein the forming of the first inorganic encapsulation layer is performed by a plasma-enhanced chemical vapor deposition (PECVD) process or a plasma-enhanced atomic layer deposition (PEALD) process.

3. The method of claim 2, wherein ultraviolet light occurs during the forming of the first inorganic encapsulation layer, and
wherein an irradiation amount of the ultraviolet light is equal to or less than about 1000 mJ/cm².

4. The method of claim 1, wherein the ratio of the sum of the flow rates of the nitrous oxide gas and the nitrogen gas to the sum of the flow rates of the ammonia gas and the hydrogen gas is equal to or greater than about 0.5.

5. The method of claim 1, wherein the forming of the second inorganic encapsulation layer comprises providing the raw material gas on the first organic encapsulation layer.

6. The method of claim 1, wherein the first inorganic encapsulation layer comprises at least one of silicon oxide (SiOₓ), silicon nitride (SiNₓ), or silicon oxynitride (SiOₓN_{y}).

7. The method of claim 1, wherein the raw material gas further comprises a silane (SiH₄) gas.

8. The method of claim 1, wherein the forming of the first organic encapsulation layer is performed by a flash evaporation process, a screen printing process, or an inkjet process.

9. The method of claim 1, further comprising:
forming a second organic encapsulation layer by applying an organic material on the second inorganic encapsulation layer after the forming of the second inorganic encapsulation layer; and
forming a third inorganic encapsulation layer on the second organic encapsulation layer, the forming of the third inorganic encapsulation layer comprising:
providing the raw material gas on the second organic encapsulation layer.

10. The method of claim 9, wherein the second inorganic encapsulation layer and the third inorganic encapsulation layer comprise at least one of silicon oxide (SiOₓ), silicon nitride (SiNₓ), or silicon oxynitride (SiOₓN_{y}).

11. The method of claim 1, wherein the organic light-emitting device comprises:
a first electrode;
a second electrode facing the first electrode and adjacent to the encapsulation member; and
a light-emitting layer between the first electrode and the second electrode and being for generating light,
wherein the light is emitted in a direction from the first electrode toward the second electrode.

12. A method of manufacturing a display device, the method comprising:
preparing an organic light-emitting device; and
forming an inorganic layer by depositing an inorganic material on the organic light-emitting device, the forming of the inorganic layer comprising:
depositing a raw material gas on the organic light-emitting device by using plasma,
wherein the raw material gas comprises a silane (SiH₄) gas, a nitrous oxide (N₂O) gas, a nitrogen (N₂) gas, an ammonia (NH₃) gas, and a hydrogen (H₂) gas, and
wherein a ratio of a sum of flow rates of the nitrous oxide gas and the nitrogen gas to a sum of flow rates of the ammonia gas and the hydrogen gas is equal to or less than about 1.1.

13. The method of claim 12, further comprising:
forming an organic layer by applying an organic material on the inorganic layer; and
forming an upper inorganic layer by depositing an inorganic material on the organic layer.

14. The method of claim 13, wherein the forming of the upper inorganic layer comprises depositing the raw material gas on the organic layer by using plasma.

15. The method of claim 12, wherein ultraviolet light occurs during the forming of the inorganic layer, and
wherein an irradiation amount of the ultraviolet light is equal to or less than about 1000 mJ/cm².

16. The method of claim 12, wherein the forming of the inorganic layer is performed by a plasma-enhanced chemical vapor deposition (PECVD) process or a plasma-enhanced atomic layer deposition (PEALD) process.

17. The method of claim 12, wherein the inorganic layer includes at least one of silicon oxide (SiOₓ) silicon nitride (SiNₓ), or silicon oxynitride (SiOₓN_{y}).

18. The method of claim 12, wherein the ratio of the sum of the flow rates of the nitrous oxide gas and the nitrogen gas to the sum of the flow rates of the ammonia gas and the hydrogen gas is equal to or greater than about 0.5.
